(19) United States
(12) Patent Application Publication
(10) Pub. No.: US 2016/0299427 A1
(43) Pub. Date: Oct. 13, 2016

(54) METHOD OF FORMING FINE PATTERNS

(71) Applicant: SK hynix Inc., Gyeonggi-do (KR)

(72) Inventors: Hak Joon KIM, Gyeonggi-do (KR); Bo Hye KIM, Seoul (KR); Joon Seuk LEE, Gyeonggi-do (KR); Yong Hyun LIM, Seoul (KR); Ji Young IM, Seoul (KR)

(21) Appl. No.: 14/823,813

(22) Filed: Aug. 11, 2015

(30) Foreign Application Priority Data
Apr. 9, 2015 (KR) 10-2015-0050478

(51) Int. Cl. G03F 7/00; G03F 7/38; G03F 7/32; H01L 21/768; G03F 7/20

(52) U.S. Cl. CPC G03F 7/0035; H01L 21/76816; G03F 7/20; G03F 7/325; G03F 7/38

(57) ABSTRACT

A method of forming fine patterns includes performing an exposure process to generate acids in first regions of a chemically amplified resist (CAR) layer, removing the exposed first regions using a first development process to form a first resist pattern, diffusing acids in sidewall portions of the first resist pattern into a bulk region of the first resist pattern to form second regions in which the acids are diffused and to form a plurality of third regions between the second regions, and removing the third regions using a second development process to form second resist patterns.

### CROSS-REFERENCE TO RELATED APPLICATION

The present application claims priority under 35 U.S.C. 119(a) to Korean Application No. 10-2015-0050478 filed on Apr. 9, 2015, in the Korean Intellectual Property Office, which is incorporated herein by reference in its entirety.

### BACKGROUND

1. Technical Field

Various embodiments of the present disclosure relate to semiconductor technologies and, more particularly, to methods of forming fine patterns.

2. Related Art

In the fabrication of semiconductor devices, a lot of effort has been focused on integrating more patterns in a limited area of a semiconductor substrate. That is, attempts to increase the integration density of semiconductor devices have typically resulted in the formation of finer and finer patterns, now being on the nano-scale level. Various techniques have been proposed to form fine patterns such as small contact holes having nano-scale critical dimensions (CD).

Nano-scale patterns may be formed during the photolithography process. However, due to image resolution limits of lithography equipment used in the photolithography process, there are limitations in how fine the patterns may be formed. These limits are due to the machines themselves, as well as the wavelengths of light that are used in the photolithography process. To further increase integration, it is therefore necessary to develop methods to overcome the current limitations.

A double patterning technology(DPT) or a spacer patterning technology(SPT) have been proposed to overcome the resolution limits of the lithography process. However, the double patterning technology and the spacer patterning technology requires deposition of multiple material layers, multiple exposure steps, multiple etch steps, and/or multiple cleaning steps. Thus, if the double patterning technology or the spacer patterning technology is employed, the fabrication process becomes more complex and costly. Accordingly, various techniques for overcoming resolution limits of the lithography equipment have been tried to form fine patterns.

### SUMMARY

Various embodiments are directed to methods of forming fine patterns.

According to an embodiment, there is provided a method of forming fine patterns. The method includes exposing first regions of a chemically amplified resist (CAR) layer to generate acids in the first regions, forming a first resist pattern by first developing the exposed first regions to form first opening holes, forming second regions and third regions in the first resist pattern, wherein the second regions are formed by diffusing acids remaining in sidewall portions of the first resist pattern and the third regions are surrounded by the second regions to be isolated from each other, and forming a second resist pattern by second developing the third regions to form second opening holes.

According to an embodiment, there is provided a method of forming fine patterns. The method includes performing an exposure process to generate acids in first regions of a chemically amplified resist (CAR) layer, removing the exposed first regions using a first development process to form a first resist pattern, diffusing acids existing in sidewall portions of the first resist pattern into a bulk region of the first resist pattern to form second regions in which the acids are diffused and to form a plurality of third regions between the second regions, and removing the third regions using a second development process to form second resist patterns.

According to an embodiment, there is provided a method of forming fine patterns. The method includes performing an exposure process to generate acids in first regions of a chemically amplified resist (CAR) layer, removing the exposed first regions using a first development process to form a first resist pattern providing first opening trenches, diffusing acids existing in sidewall portions of the first resist pattern into a bulk region of the first resist pattern to form second regions in which the acids are diffused and to form a plurality of third regions having line shapes between the second regions, and removing the third regions using a second development process to form second resist patterns providing second opening trenches between the first opening trenches.

### BRIEF DESCRIPTION OF THE DRAWINGS

Various embodiments of the present disclosure will become more apparent in view of the attached drawings and accompanying detailed description, in which:

FIGS. 1 to 8 are cross-sectional views illustrating a method of forming fine patterns according to an embodiment;

FIG. 9 is a cross-sectional view illustrating an annealing method according to an embodiment;

FIGS. 10 and 11 are cross-sectional views illustrating a diffusion promotion layer according to an embodiment;

FIGS. 12 to 16 are perspective views illustrating a method of forming fine patterns according to an embodiment; and

FIGS. 17, 18 and 19 are perspective views illustrating a method of forming fine patterns according to an embodiment.

### DETAILED DESCRIPTION OF THE EMBODIMENTS

It will be understood that although the terms such as “first,” “second,” “third,” etc. may be used herein to describe various elements, these elements should not be limited by these terms. These terms are only used to distinguish one element from another element. Thus, a first element in some embodiments could be termed a second element in other embodiments without departing from the teachings of the present disclosure.

It will also be understood that when an element is referred to as being located “under,” “beneath,” “below,” “lower” “on,” “over,” “above,” “upper,” “side,” or “aside” another element, it can be directly contact the other element, or at least one intervening element may also be present therebetween. Accordingly, the terms such as “under,” “beneath,” “below,” “lower,” “on,” “over,” “above,”“upper,” “side,” or “aside” and the like which are used are for the purpose of describing particular embodiments only and are not intended to limit the scope of the present disclosure. Other words used to describe the relationship between elements or layers should be interpreted in a like fashion (e.g., “between” versus “directly between” or “adjacent” versus “directly adjacent”).

Various embodiments of the present disclosure may be applied to fabrication of highly integrated semiconductor devices, for example, dynamic random access memory (DRAM) devices, phase-change random access memory (PCRAM) devices or resistive random access memory (ReRAM) devices. In addition, the following embodiments may be applied to fabrication of memory devices such as static random access memory (SRAM) devices, flash memory devices, magnetoresistive random access memory (MRAM) devices or ferroelectric random access memory (FeRAM) devices. The following embodiments may also be applied to fabrication of logic devices such as control devices, central processing units (CPU) or arithmetic logic units (ALU).

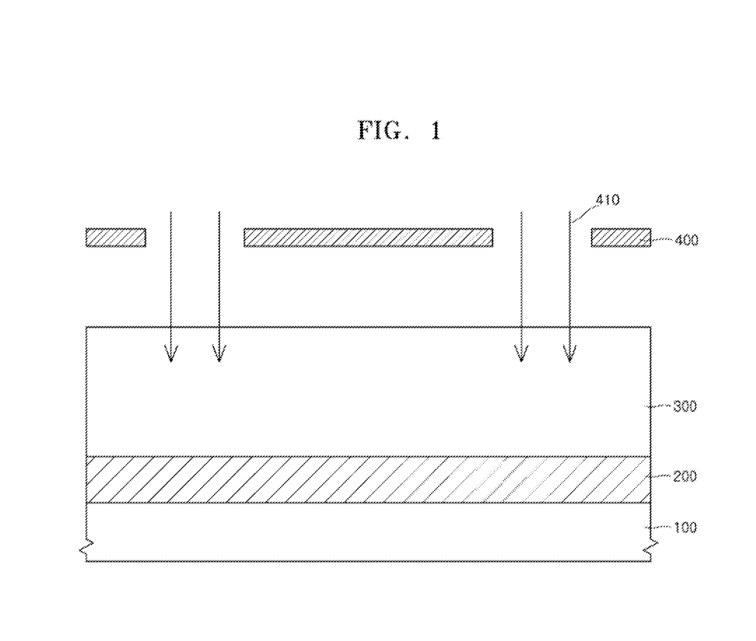

FIGS. 1 to 8 are cross-sectional views illustrating a method of forming fine patterns according to an embodiment.

FIG. 1 illustrates a step of applying an exposure process to a resist layer 300.

Referring to FIG. 1, an underlying layer 200 corresponding to an etch target layer may be formed on a substrate 00 such as a semiconductor substrate. A resist material may be coated on the underlying layer 200, and the resist material may be cured using a soft bake process to form a resist layer 300. A surface treatment process may be additionally applied to a surface of the underlying layer 200 before the resist material is coated on the underlying layer 200. For example, a surface of the underlying layer 200 may be changed into a hydrophobic surface using a silazane gas such as a hexa-methyl-di-silazane (HMDS) gas to improve adhesive strength between the underlying layer 200 and the resist layer 300. In some embodiments, before the resist material is coated on the underlying layer 200, a bottom anti-reflective coating (BARC) layer may be additionally formed on the underlying layer 200 to suppress diffuse reflection and to improve exposure accuracy during an exposure process. The BARC layer may include an organic anti-reflective coating (ARC) material or an inorganic ARC material. A top coat layer (not shown) may be additionally formed on the resist layer 300 after the resist layer 300 is formed.

The substrate 100 including the resist layer 300 may be loaded into an exposure apparatus, and an exposure process may be applied to the resist layer 300. For example, a photo mask 400 may be aligned with the substrate 100 so that the photo mask 400 is located over the resist layer 300, and exposure light 410 may be irradiated onto predetermined regions of the resist layer 300 through the photo mask 400. The exposure light 410 may be provided by any one of various light sources, for example, by an argon fluoride (ArF) laser or a krypton fluoride (KrF) laser. The photo mask 400 may be a transparent mask such as a binary mask or a phase shift mask. Alternatively, the photo mask 400 may be a reflective mask.

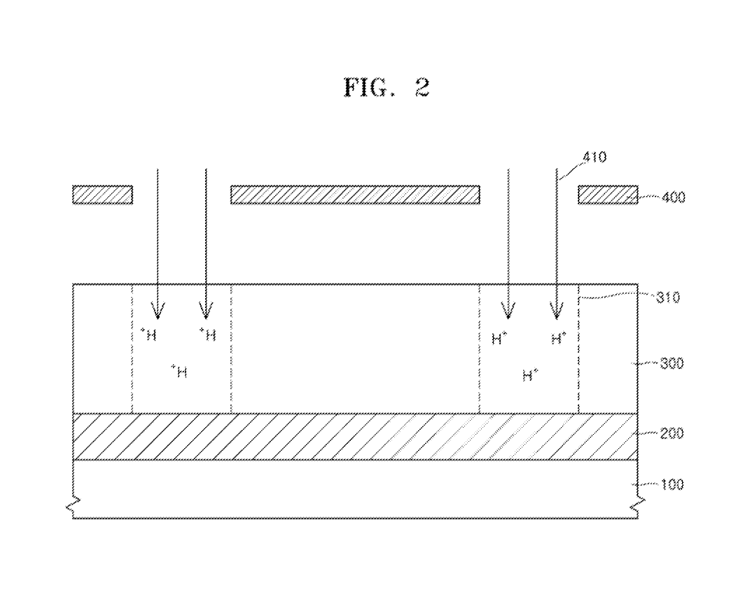

FIG. 2 illustrates that acids (i.e., hydrogen ions H⁺) are generated in first regions 310 of the resist layer 300, which are exposed to the exposure light 410.

Referring to FIG. 2, the exposure light 410 may be irradiated into the first regions 310 of the resist layer 300 using an exposure process performed with the photo mask 400. Acids (H⁺) may be generated in the first regions 310 by the exposure light 410. The resist layer 300 may include a chemically amplified resist (CAR) material. The exposure light 410 may induce photo acid generators (PAG) contained in the CAR layer 300 to generate acids (H⁺). Accordingly, the exposed first regions 310 including the acids (H⁺) may have a latent image that is the same as a pattern image of the photo mask 400.

The CAR material may have a quantum yield which is greater than 100% and may exhibit differences in solubility between an exposed region and a non-exposed region thereof due to a protecting-deprotecting reaction. The CAR material may include a polymer material as a matrix component, and the polymer material may include backbones or main chains having protecting groups. The polymer material may include poly-hydroxy-styrene (PHS) polymer. The protecting group may include tert-butyloxycarbonyl (t-BOC). The CAR material may further include an inhibitor to control contrast, solubility, and diffusivity of acids.

If the exposure light 410 generated from a light source such as an excimer laser is irradiated onto the CAR layer corresponding to the resist layer 300, the PAG contained in the CAR layer may generate acids and the acids may be diffused. After the resist layer 300 is exposed to the exposure light 410, a post exposure bake (PEB) process may be applied to the exposed resist layer 300. The PEB process may be performed at a temperature of about 100 degrees Celsius to about 110 degrees Celsius.

During the PEB process, a chemical reaction for deprotecting the protecting groups may occur, The protecting groups may include acid labile groups (e.g., t-BOC) that can be removed by acids. The protecting groups such as t-BOC may react on acids to be converted into hydroxyl groups (—OH groups). The protecting groups such as t-BOC may protect the n chains of the polymer material to have fat-soluble properties. However, the hydroxyl groups into which the protecting groups are converted may exhibit a relatively high solubility in a developer corresponding to a weak alkaline solution. Thus, the first regions 310 exposed to the exposure light 410 may be selectively removed in a subsequent first development process. Accordingly if the first regions 310 of the CAR layer 300 are converted by a de-protecting reaction to have hydroxyl groups, the exposed first regions 310 may have the same features as the pattern image of the photo mask 400,

If acids of a molecule generated from the FAG contained in the CAR layer 300 are diffused, a deprotecting reaction may be accelerated by a catalytic reaction. As process temperature and process time of the PEB process increase, the diffusion of acids may continuously occur. Thus, the CAR layer 300 may further include a reaction inhibitor to control the diffusivity of acids and to suppress generation of failed patterns due to contamination. The CAR layer 300 may include an alicyclic polymer material such as a methacrylate material or a polymer material such as a cyclic olefin/maleic anhydride (COMA) material.

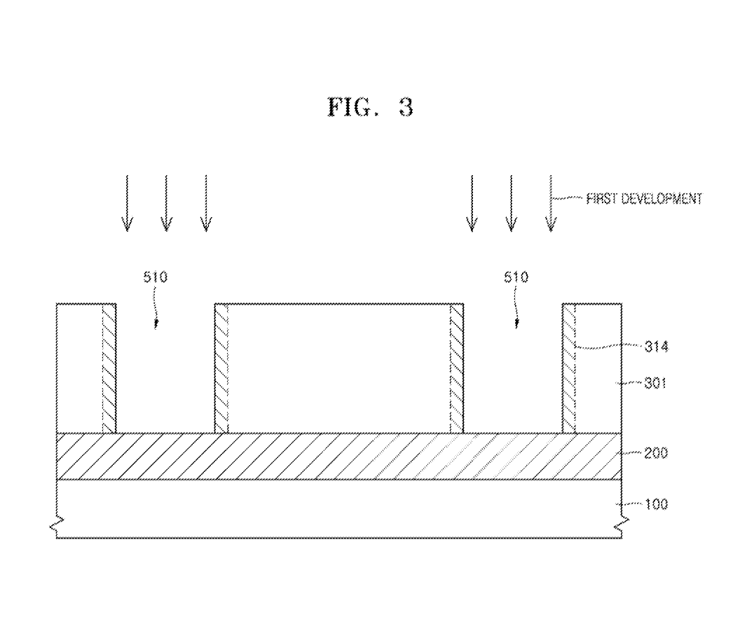

FIG. 3 illustrates a step of forming a first resist pattern 301 providing first openings 510.

Referring to FIG, 3, the exposed first regions (310 of FIG. 2) having a relatively high solubility in an alkaline solution may be selectively removed using a first development process to form the first resist pattern 301 providing the first openings 510. The first development process may be performed with an alkaline developer, and the first openings 510 may be formed to expose portions of the underlying layer 200. The alkaline developer may be a typical positive tone developer. For example, the first development process may be performed using a tetramethyl ammonium hydride (TMAH) solution having a concentration of 2.35 wt % as a developer.

The first resist pattern 301 formed by the first development process may correspond to a positive pattern that provides the first openings 510 formed by transfer of the pattern image of the photo mask (400 of FIG. 2). A sidewall portion 314 of each of the first openings 510 may have a sidewall surface exposed by removing the exposed first region 310, and a portion of acids diffused from the exposed first region 310 may exist in the sidewall portion 314.

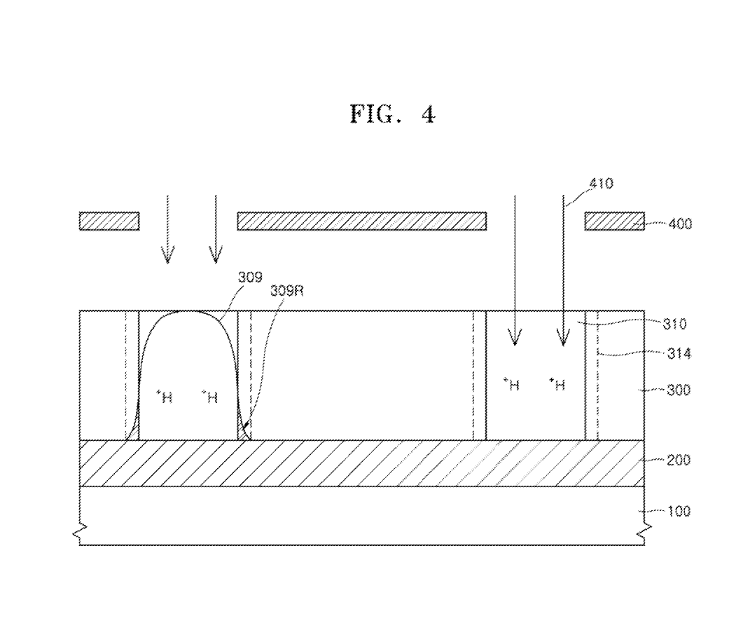

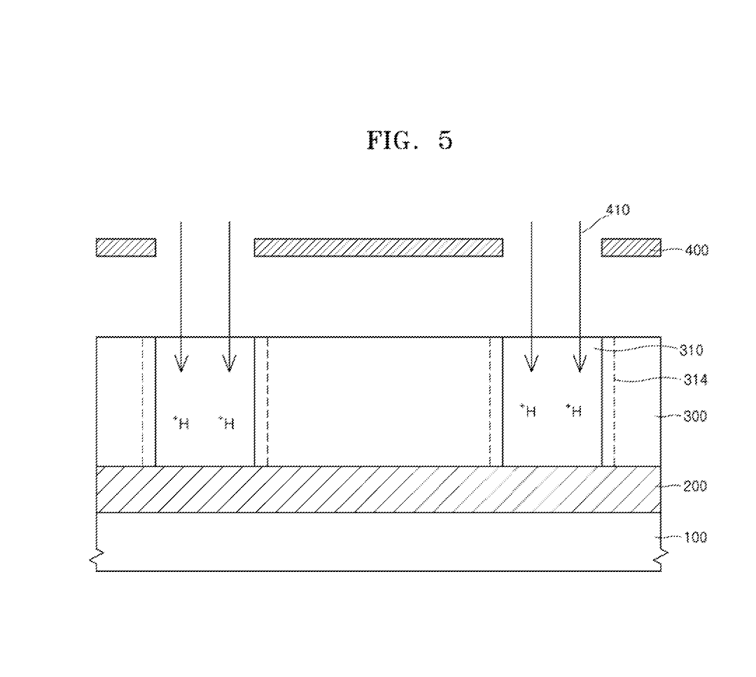

FIGS. 4 and 5 illustrate a distribution of acids in each of the exposed first regions 310.

Referring to FIG. 4, the acids generated and diffused by the exposure process and the PEB process may be distributed in the exposed first regions 310. The acids may be generated from the PAG contained in the resist layer 300 in response to the exposure light 410 irradiated onto the first regions 310 and may also be diffused by the exposure light 410. In addition, while the PEB process is performed, the acids may participate in the deprotecting reaction and may be diffused. As illustrated by curve 309, most of the adds may be distributed in the exposed first regions 310 but portions 309R of the acids may be diffused into the sidewall portions 314 (of the first openings 510 of FIG, 3) adjacent to the exposed first regions 310. As illustrated in FIGS. 4 and 5, the acids may be distributed even in the sidewall portions 314 adjacent to the exposed first regions 310. Thus, portions of the acids may exist in the sidewall portions 314 of the first openings 510 even after the exposed first regions 310 are removed, as illustrated in FIG. 3, Since an acid concentration of the sidewall portions 314 is lower than an acid concentration of the exposed first regions 310, the sidewall portions 314 may not be removed during the first development process. That is, the sidewall portions 314 may remain even after the first development process.

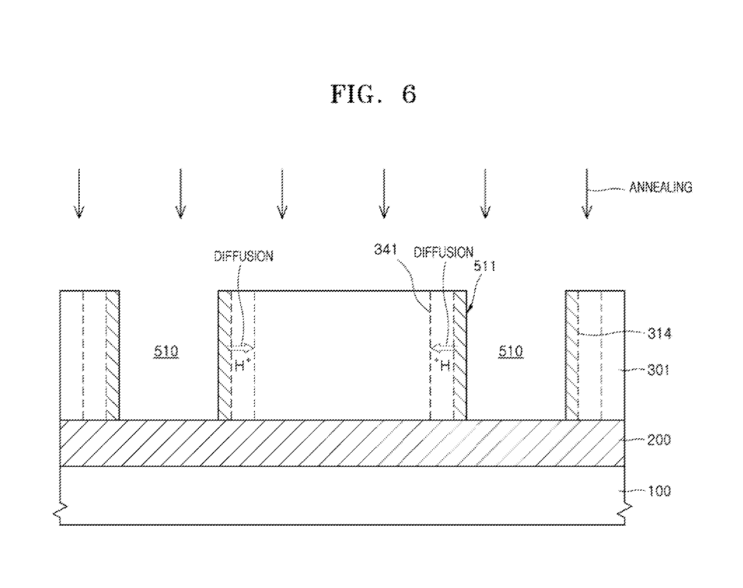

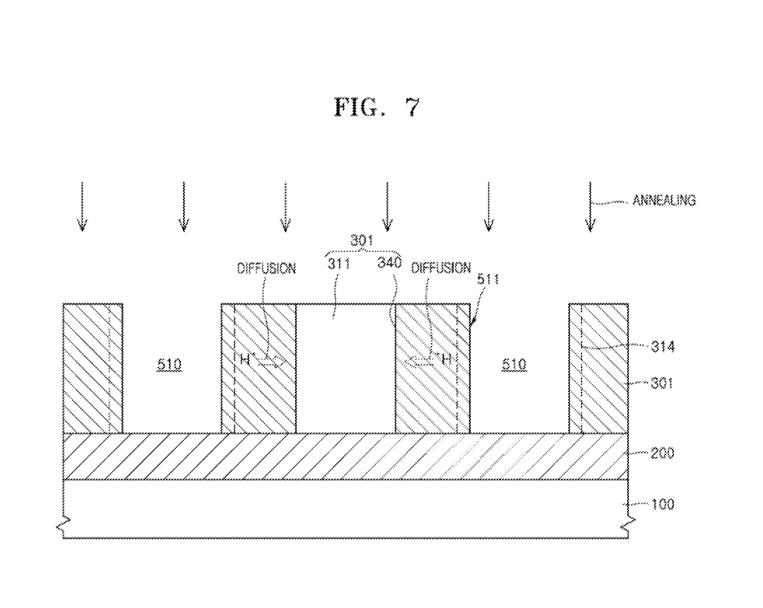

FIGS. 6 and 7 illustrate a step of forming second regions 40 in the first resist pattern 301.

Referring to FIG. 6, the first resist pattern 301 providing the first openings 510 may be annealed to diffuse the acids remaining in the sidewall portions 314 into a bulk region thereof. That is, the acids in the sidewall portions 314 may be diffused into an inside region of the first resist pattern 301 due to heat provided by the annealing process, thereby forming diffused regions 341 adjacent to the sidewall portions 314. As a result, the diffused regions 341 may be in contact with sidewall surfaces of the sidewall portions 314 opposite to sidewall surfaces 511 of the first openings 510. The diffused regions 341 may be expanded into an inside region of the first resist pattern 301 to form second regions 340 during the annealing process. The annealing process may be controlled so that the second regions 340 do not reach a central portion of a bulk region of the first resist pattern 301. A third region 311 without acids may be defined in a central portion of the bulk region of the first resist pattern 301. The diffusion range of the acids, that is, the expansion range of the second regions 340 may depend on the process temperature of the annealing process, the process time of the annealing process and the content of the reaction inhibitor contained in the first resist pattern 301. Thus, line widths of the second and third regions 340 and 311 in the first resist pattern 301 may be appropriately controlled by adjusting at least one selected from the group consisting of process temperature of the annealing process, process time of the annealing process, and content of the reaction inhibitor contained in the first resist pattern 301.

The acids diffused into the second regions 340 of the first resist pattern 301 may induce a chemical reaction for deprotecting the protecting groups of the polymer material included in the second regions 340. The polymer material in the second regions 340 of the first resist pattern 301 may have a relatively high solubility in an alkaline developer due to the deprotecting reaction, and may have resistance to organic solvents. As described above, the third region 311 of the first resist pattern 301 does not contain acids. Accordingly, polymers in a resist material of the third region 311 may be protected by protecting groups to have a resistance to an alkaline solution but to have relatively high solubility in organic solvents as compared with the second regions 340. The second regions 340 of the first resist pattern 301 may have a relatively high solubility in an alkaline solution due to the deprotecting reaction. Accordingly, the second regions 340 of the first resist pattern 301 may be changed in chemical property to have a relatively low solubility to an organic solvent as compared with the third region 311 of the first resist pattern 301. Thus, a solubility of the second regions 340 of the first resist pattern 301 in an organic solvent may be different from a solubility of the third region 311 of the first resist pattern 301 in an organic solvent. That is, a solubility of the second regions 340 in an organic solvent may be lower than the solubility of the third region 311 in an organic solvent. Therefore, the third region 311 may be selectively removed using a subsequent development process (i.e., a second development process) even without an additional exposure process since the second regions 340 exhibit a different solubility from the third region 311 in an organic solvent.

The annealing process may be performed at a temperature which is higher than a process temperature of the PEB process. The annealing temperature may be identical to the baking temperature of the PEB process. However, the diffusivity of the acids during the annealing process may be so low that it takes a long time to control line widths of the second and the third regions 340 and 311. Thus, the annealing temperature may be set higher than the baking temperature of the PEB process to reduce the process time of the annealing process. For example, the annealing temperature may be set higher than the baking temperature of the PEB process by about degrees Celsius to about 30 degrees Celsius. In some embodiments, the annealing temperature may be set within the range of about 120 degrees Celsius to about 140 degrees Celsius. In some other embodiments, the annealing temperature may be identical to a glass transition temperature Tg of the polymer material included in the first resist pattern 301. Specifically, the glass transition temperature Tg of the backbones of the polymer material may be within the range of about 110 degrees Celsius to about 130 degrees Celsius, and the annealing temperature may be identical to the glass transition temperature Tg of the backbones of the polymer material. In such a case, the first resist pattern 301 may flow to efficiently control the diffusion of the acids

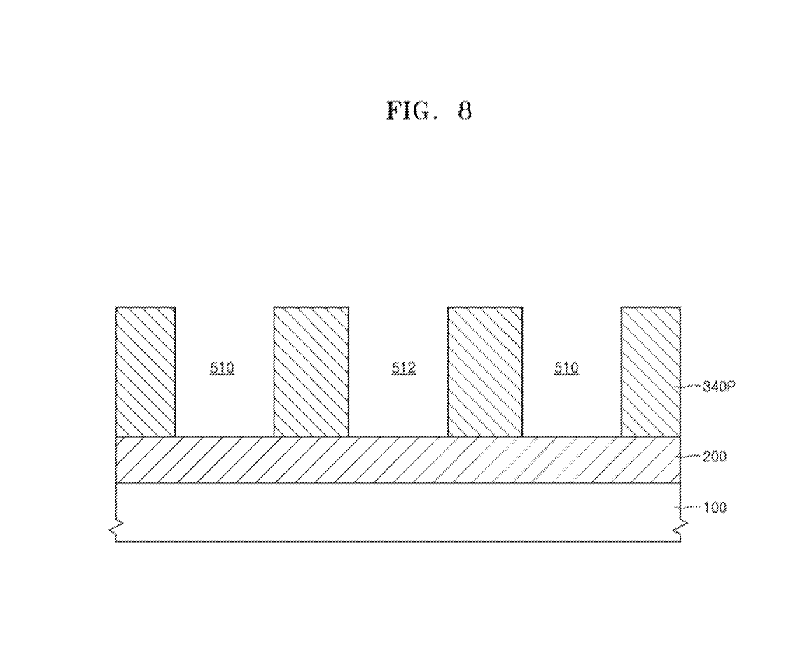

FIG. 8 illustrates a step of forming a second resist pattern 340P providing a second opening 512 with the first openings 510.

Referring to FIG. 8, the third region (311 of FIG. 7) of the first resist pattern 301 may be selectively removed using a second development process. The second regions (340 of FIG. 7) may have a relatively high solubility to an alkaline solution and may have a relatively low solubility to an organic solvent as compared with the third region (311 of FIG. 7), due to the deprotecting reaction. Thus, the third region (311 of FIG. 7) may be selectively removed using the second development process that employs an organic solution containing an organic solvent as a developer, thereby forming the second opening 512. In some embodiments, the organic developer used in the second development process may include acetate, alcohol, ether, ester or ketone.

In the second development process, the third region 311 of the first resist pattern 301 may be removed to form the second resist pattern 340P providing the second opening 512. A width of each of the second regions 340 of the first resist pattern 301 may be determined by the diffusion of the acids which is due to the annealing process, and the second regions 340 are formed to have the same width during the annealing process, The second opening 512 may be formed at a central portion of the first resist pattern 301 between two adjacent first openings 510. The second opening 512 may be formed using the acid diffusion and the second development process utilizing an organic developer without use of an exposure process for selectively exposing the third region 311 of the first resist pattern 301. Since the second opening 512 can be formed without use of the exposure process for selectively exposing the third region 311 of the first resist pattern 301, the second opening 512 may be self-aligned between the first openings 510 even without any alignment processes. Thus, the method of forming fine patterns according to the above embodiment may not require an accurate alignment process such as an alignment process used in a double pattering process or a spacer pattering process.

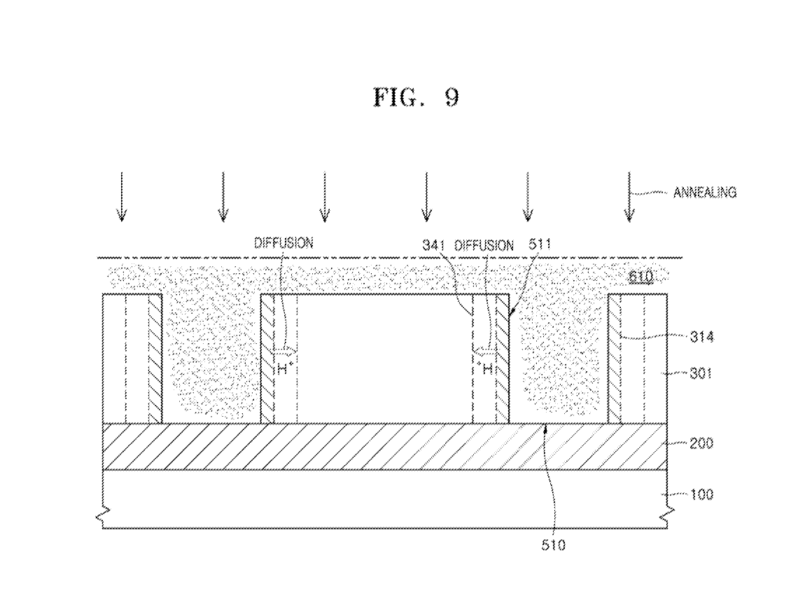

FIG. 9 is a cross-sectional view illustrating another example of the annealing process used in the embodiment described with reference to FIGS. 1 to 8.

Referring to FIG. 9, the annealing process may include supplying an acid ambient gas 610 onto a surface (particularly, the sidewall surfaces 511) of the first resist pattern 301 providing the first openings 510. The acid ambient gas 610 may include a hydrochloric acid (HCl) gas. The acid ambient gas 610 may be introduced to accelerate a phenomenon where the acids in the sidewall portions 314 of the first openings 510 are diffused into a bulk region of the first resist pattern 301.

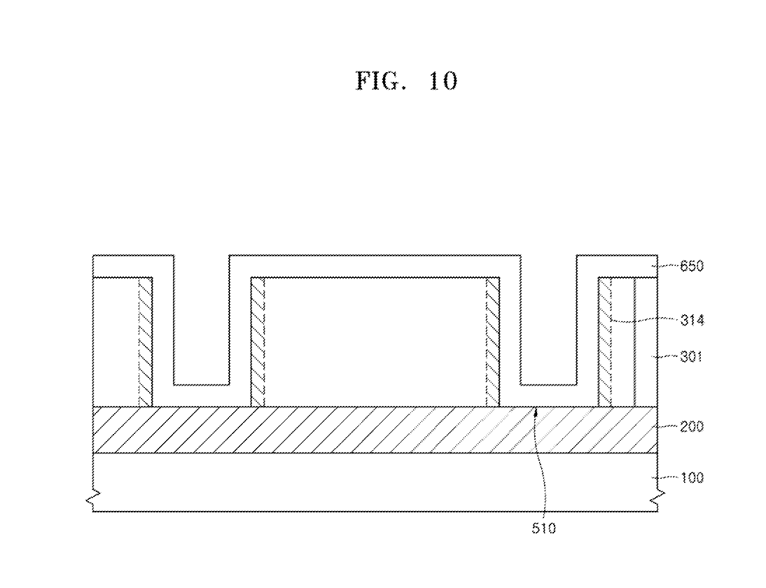

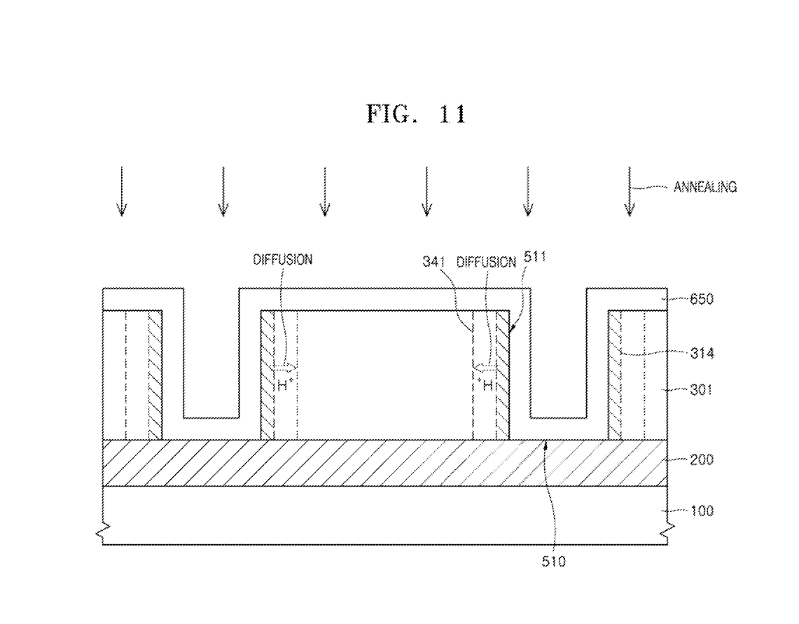

FIGS. 10 and 11 are cross-sectional views illustrating a step of forming a diffusion promotion layer 650 applicable to the embodiment described with reference to FIGS. 1 to 8.

Referring to FIGS. 10 and 11, the diffusion promotion layer 650 may be formed to cover a surface (particularly, the sidewall surfaces 511 of the first openings 510) of the first resist pattern 301 before the annealing process described with reference to FIG. 6 is performed. The diffusion promotion layer 650 may be introduced to accelerate a phenomenon where the acids in the sidewall portions 314 of the first openings 510 are diffused into a bulk region of the first resist pattern 301. That is, the diffusion of the acids in the first resist pattern 301 may be accelerated during the annealing process because of the presence of the diffusion promotion layer 650 covering the first resist pattern 301.

The diffusion promotion layer 650 may be a material layer having a pH of less than 7. The diffusion promotion layer 650 may be formed by coating a water-soluble polymer material having a pH of less than 7 on the first resist pattern 301. More specifically the diffusion promotion layer 650 may be formed by coating a polymer material having an average molecular weight of less than 8000 and a pH of less than 7. The diffusion promotion layer 650 may provide an arid environment to accelerate a phenomenon where the acids existing in the sidewall portions 314 of the first openings 510 is diffused into a bulk region of the first resist pattern 301 during the annealing process. As a result, the diffusivity of the acids in the first resist pattern 301 may increase during the annealing process due to the presence of the diffusion promotion layer 650.

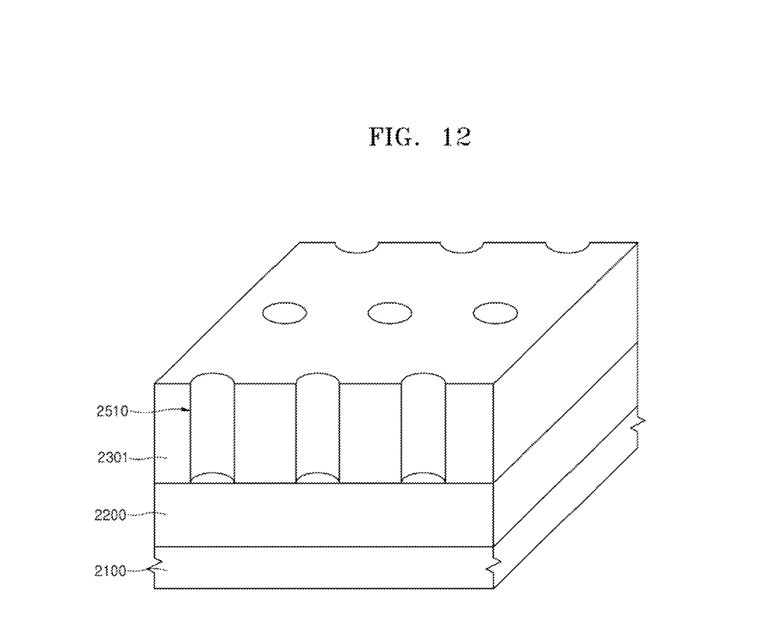

FIGS. 12 to 16 are perspective views illustrating a method of forming fine patterns according to another embodiment.

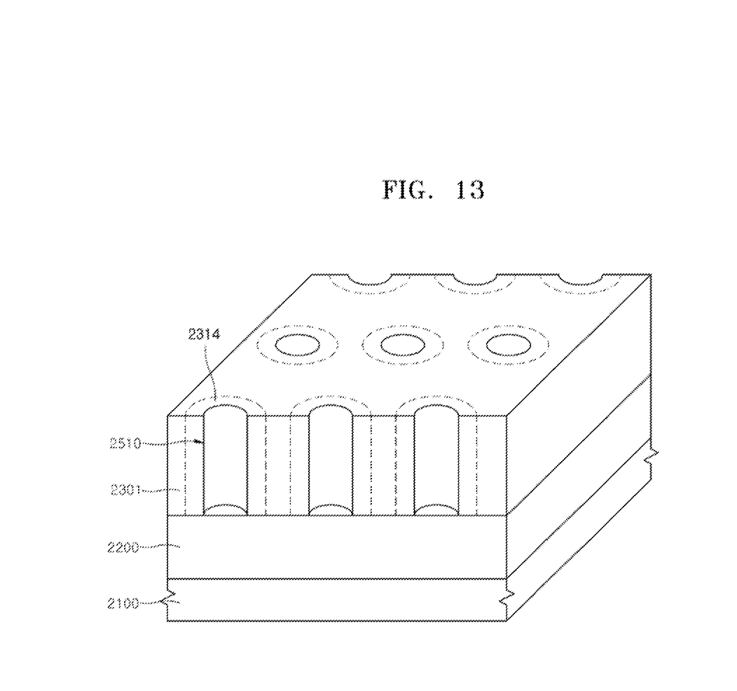

FIGS. 12 and 13 illustrate a step of forming a first resist pattern 2301 providing first opening holes 2510.

Referring to FIG. 12, an underlying layer 2200 corresponding to an etch target layer may be formed on a semiconductor substrate 2100. A resist material may then be coated on the underlying layer 2200, and the resist material may be cured using a soft bake process to form a resist layer. First regions of the resist layer may be selectively exposed using an exposure process, and the exposed first regions of the resist layer may be selectively removed using a first development process. The first development process may be performed using an alkaline developer. As a result of the first development process, the exposed first regions of the resist layer may be selectively removed to form the first resist pattern 2301 providing the first opening holes 2510 that expose portions of the underlying layer 2200.

The first resist pattern 2301 formed by the first development process may correspond to a positive pattern that provides the first opening holes 2510 formed by transfer of a pattern image of a photo mask (not shown) used in the exposure process. As illustrated in FIG. 13, a sidewall portion 2314 of each of the first opening holes 2510 may have a sidewall surface exposed by removing the exposed first region, and a portion of acids diffused from the exposed first region may exist in the sidewall portion 2314. Since an acid concentration of the sidewall portions 2314 is lower than an acid concentration of the exposed first regions, the sidewall portions 2314 may not be removed during the first development process. That is, the sidewall portions 2314 may remain even after the first development process.

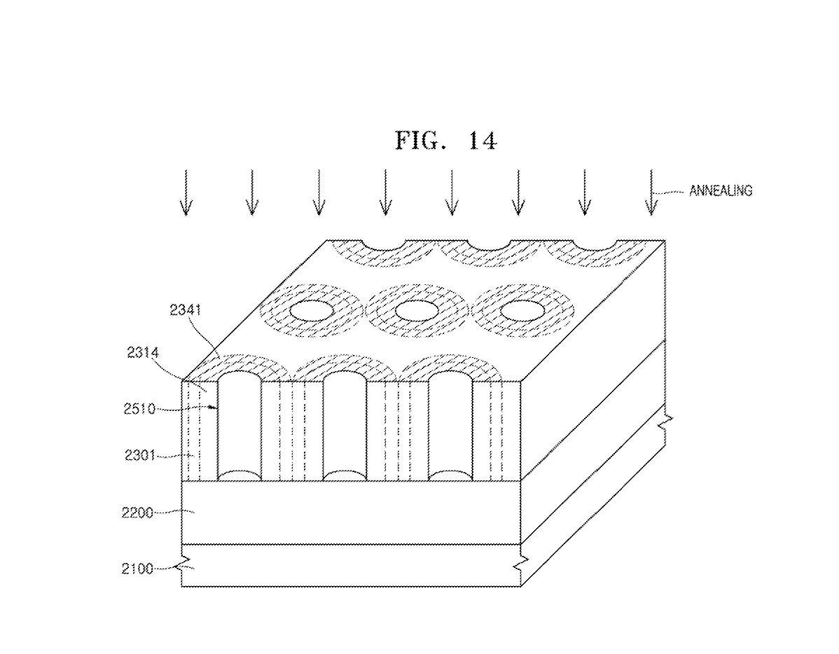

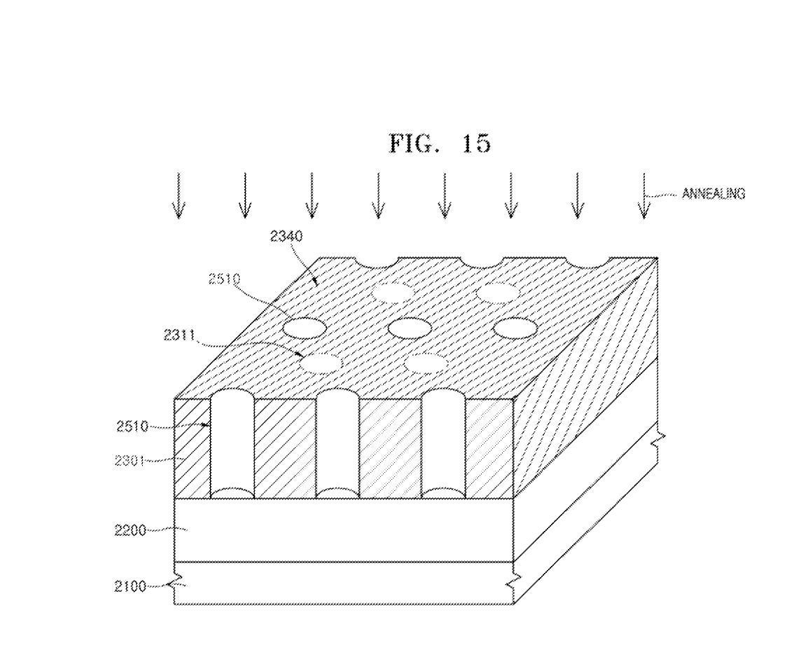

FIGS. 14 and 15 illustrate a step of forming a second region 2340 in the first resist pattern 2301.

Referring to FIG. 14, the first resist pattern 2301 providing the first opening holes 2510 may be annealed to diffuse the acids remaining in the sidewall portions 2314 into a bulk region thereof. That is, the acids existing in the sidewall portions 2314 may be diffused into an inside region of the first resist pattern 2301 due to heat provided by the annealing process, thereby forming diffused regions 2341 adjacent to the sidewall portions 2314. During the annealing process, the diffused regions 2341 may be continuously expanded into an inside region of the first resist pattern 2301 to contact each other. The diffused regions 2341 contacting each other may constitute a single second region 2340, as illustrated in FIG. 15. A plurality of third regions 2311 without acids may be defined between the first opening holes 2510. That is, the annealing process may be controlled so that each of the plurality of third regions 2311 without acids is located at a central portion of a region surrounded by four adjacent first opening holes 2510. In some embodiments, each of the plurality of third regions 2311 without acids may be located at a central portion of a region surrounded by three adjacent ones of the first opening holes 2510, according to an array of the first opening holes 2510. The third regions 2311 may be isolated from each other by the second region 2340. That is, the third regions 2311 may be formed to have isolated island shapes.

The acids diffused into the second region 2340 of the first resist pattern 2301 may induce a chemical reaction for deprotecting the protecting groups of the polymer material included in the second region 2340. The polymer material in the second region 2340 of the first resist pattern 2301 may have a relatively high solubility in an alkaline developer due to the deprotecting reaction, and may have a resistance to an organic solvent. As described above, the third regions 2311 of the first resist pattern 2301 does not contain acids. Accordingly, polymers in a resist material of the third regions 2311 may be protected by protecting groups to have a resistance to an alkaline solution but to have a relatively high solubility to an organic solvent as compared with the second region 2340.

The annealing process for forming the second region 2340 may be performed using the same recipe as described with reference to FIG. 9. That is, the annealing process may be performed using an acid gas as an ambient gas. In some embodiments, the diffusion promotion layer 650 described with reference to FIGS. 10 and 11 may be additionally formed to cover the first resist pattern 2301 before the annealing process is performed.

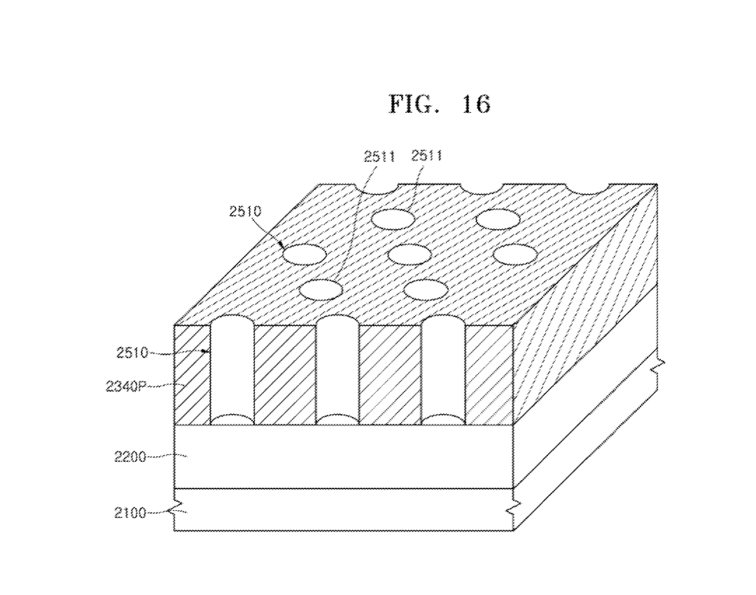

FIG. 16 illustrates a step of forming a second resist pattern 2340P providing second opening holes 2511 with the first opening holes 2510.

Referring to FIG. 16, the third region (2311 of FIG. 15) of the first resist pattern 2301 may be selectively removed using a second development process. The second regions 2340 of FIG. 15) may have a relatively high solubility to an alkaline solution and may have a relatively low solubility to an organic solvent as compared with the third regions (2311 of FIG. 15), due to the deprotecting reaction. Thus, the third regions (2311 of FIG. 15) may be selectively removed using the second development process that employs an organic solution containing an organic solvent as a developer, thereby forming the second opening holes 2511. In some embodiments, the organic developer used in the second development process may include acetate, alcohol, ether, ester or ketone.

In the second development process, the third regions 2311 of the first resist pattern 2301 may be removed to form the second resist pattern 2340P providing the second opening holes 2511. Each of the second opening holes 2511 may be formed at a central portion of a region surrounded by four adjacent first opening holes 2510. In some embodiments, each of the second opening holes 2511 may be formed at a central portion of a region surrounded by three adjacent first opening holes 2510, according to an array of the first opening holes 2510. In some other embodiments, each of the second opening holes 2511 may be formed at a central portion of a region surrounded by five or more adjacent first opening holes 2510, according to an array of the first opening holes 2510.

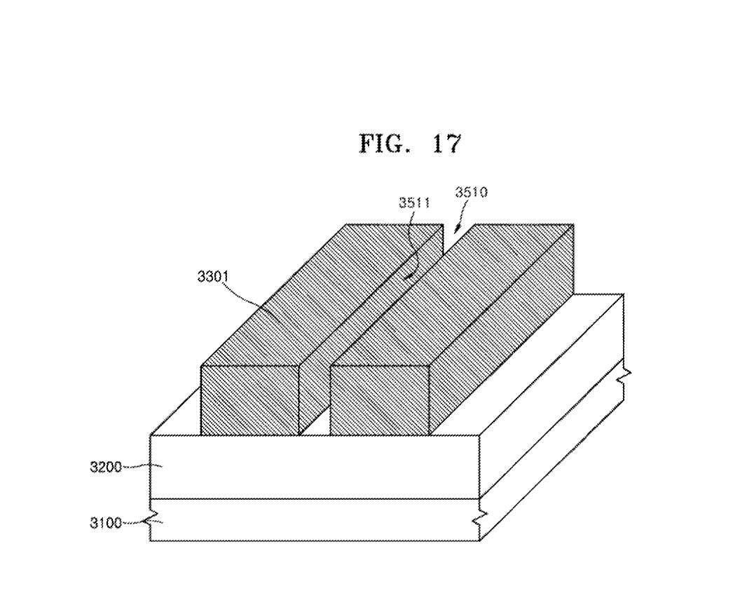

FIGS. 17, 18 and 19 are perspective views illustrating a method of forming fine patterns according to still another embodiment.

FIG. 17 illustrates a step of forming first resist patterns 3301 providing first opening trenches 3510.

Referring to FIG, 17, an underlying layer 3200 may be formed on a semiconductor substrate 3100. A resist material may then be coated on the underlying layer 3200, and the resist material may be cured using a soft bake process to form a resist layer. First regions of the resist layer may be selectively exposed using an exposure process, and the exposed first regions of the resist layer may be selectively removed using a first development process. The first development process may be performed using an alkaline developer. As a result of the first development process, the exposed first regions of the resist layer may be selectively removed to form the first resist patterns 3301 providing the first opening trenches 3510 that expose portions of the underlying layer 3200. The first resist patterns 3301 may be formed so that the first opening trenches 3510 extend in one direction to have a line shape or a band shape.

The first resist patterns 3301 formed by the first development process may correspond to positive patterns that provide the first opening trenches 3510 formed by transfer of a pattern image of a photo mask (not shown) used in the exposure process. As illustrated in FIG. 17, sidewall surfaces 3511 of the first opening trenches 3510 may be exposed by removing the exposed first regions, and a portion of acids diffused from each of the exposed first regions may exist in sidewall portions located at both sides of each of the first opening trenches 3510.

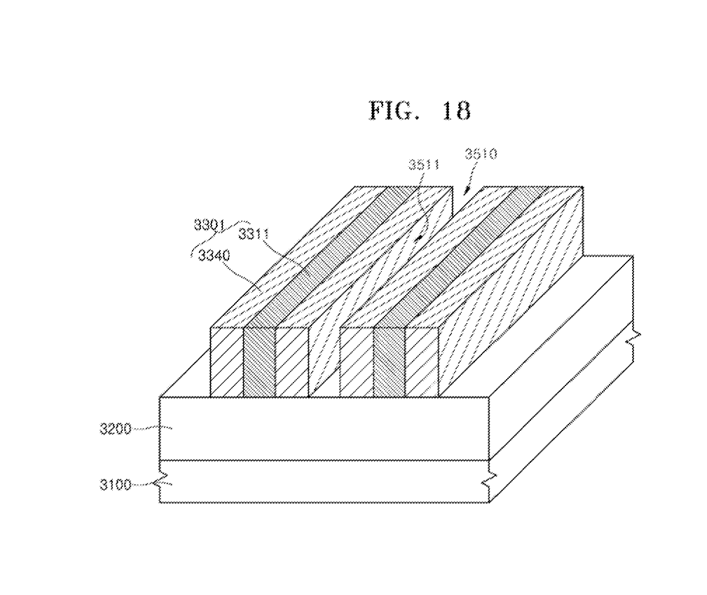

FIG. 18 illustrates a step of forming second regions 3340 in the first resist patterns 3301.

Referring to FIG. 18, the first resist patterns 3301 providing the first opening trenches 3510 may be annealed to diffuse the acids remaining in the sidewall portions into bulk regions thereof. That is, the acids existing in the sidewall portions may be diffused into inside regions of the first resist patterns 3301 due to heat provided by the annealing process, thereby forming second regions 3340 adjacent to the sidewall portions of the first opening trenches 3510. During the annealing process, the second regions 3340 may be continuously expanded to inside regions of the first resist patterns 3301. The annealing process may be controlled so that the second regions 3340 formed at both sidewall portions of each first resist pattern 3301 do not contact each other. A third region 3311 without acids may be defined between the second regions 3340 in each of the first resist patterns 3301.

The acids diffused into the second regions 3340 of the first resist patterns 3301 may induce a chemical reaction for deprotecting the protecting groups of the polymer material included in the second regions 3340. The polymer material in the second regions 3340 of the first resist patterns 3301 may have a relatively high solubility in an alkaline developer due to the deprotecting reaction, and may have a resistance to organic solvents. As described above, the third regions 3311 of the first resist patterns 3301 does not contain acids. Accordingly, polymers in a resist material of the third regions 3311 may be protected by protecting groups to have a resistance to an alkaline solution and to have a relatively high solubility to an organic solvent as compared with the second regions 3340.

The annealing process for forming the second regions 3340 may be performed using the same recipe as described with reference to FIG. 9. That is, the annealing process may be performed using an acid gas as an ambient gas. In some embodiments, the diffusion promotion layer 650 described with reference to FIGS. 10 and 11 may be additionally formed to cover the first resist patterns 3301 before the annealing process is performed.

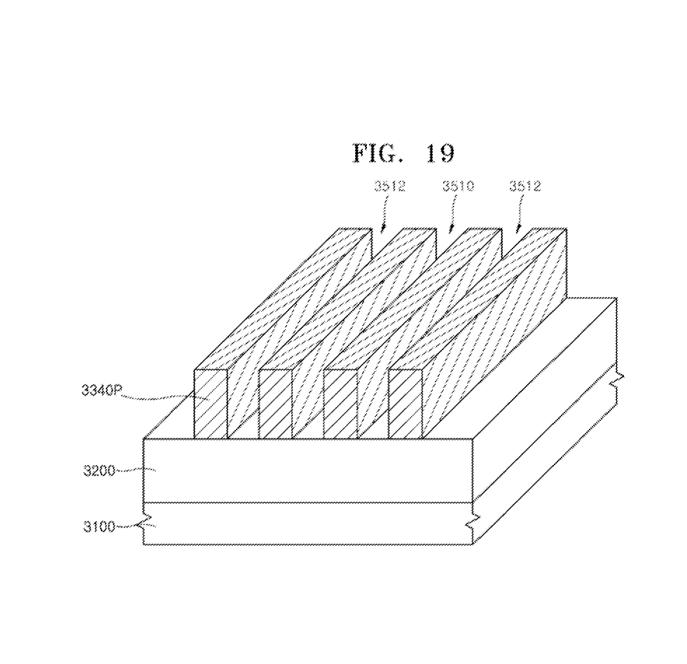

FIG. 19 illustrates a step of forming second resist patterns 3340P providing second opening trenches 3512 with the first opening trenches 3510.

Referring to FIG. 19, the third region (3311 of FIG. 18) of the first resist patterns 3301 may be selectively removed using a second development process. The second regions (3340 of FIG. 18) may have a relatively high solubility to an alkaline solution and may have a relatively low solubility to an organic solvent as compared with the third regions (3311 of FIG. 18), due to the deprotecting reaction. Thus, the third regions (3311 of FIG. 18) may be selectively removed using the second development process that employs an organic solution containing an organic solvent as a developer, thereby forming the second opening trenches 3512. In some embodiments, the organic developer used in the second development process may include acetate, alcohol, ether, ester or ketone.

In the second development process, the third regions 3311 of the first resist patterns 3301 may be removed to form the second resist patterns 3340P providing the second opening trenches 3512. The second opening trenches 3512 may be formed between the first opening trenches 3510. That is, the first opening trenches 3510 and the second opening trenches 3512 may be alternately and repeatedly arrayed in one direction.

According to the embodiments described above, nano-scale structures can be fabricated on a large-sized substrate using a single exposure process, diffusion of acids remaining in a CAR layer, and first and second development processes that are distinct from each other. The nano-scale structures may be used in fabrication of polarizing plates or in formation of reflective lens of reflective liquid crystal display (LCD) units, The nano-scale structures may also be used in fabrication of separate polarizing plates as well as in formation of polarizing parts including display panels. For example, the nano-scale structures may be used in processes for directly forming the polarizing parts on array substrates including thin film transistors or color filter substrates. Further, the nano-scale structures may be used in molding processes for fabricating nanowire transistors, memories, electronic/electric components such as nano-scaled interconnections, catalysts of solar cells and fuel cells, etch masks, organic light emitting diodes (OLEDs), and gas sensors.

The methods according to the aforementioned embodiments and structures formed thereby may be used in fabrication of integrated circuit (IC) chips. The IC chips may be supplied to users In a raw wafer form, in a bare die form or in a package form. The IC chips may also be supplied in a single package form or in a multi-chip package form. The IC chips may be integrated in intermediate products such as mother boards or end products to constitute signal processing devices. The end products may include toys, low-end application products, or high-end application products such as computers. For example, the end products may include display units, keyboards, or central processing units (CPUs).

The embodiments of the present disclosure have been disclosed above for illustrative purposes. Those of ordinary skill in the art will appreciate that various modifications, additions, and substitutions are possible, without departing from the scope and spirit of the present disclosure as claimed below.

What is claimed is:

1. A method of forming fine patterns, the method comprising:
exposing first regions of a chemically amplified resist (CAR) layer to generate acids in the first regions;
forming a first resist pattern by first developing the exposed regions to form first opening holes;
forming second regions and third regions in the first resist pattern, wherein the second regions are formed by diffusing acids remaining in sidewall portions of the first resist pattern and the third regions are surrounded by the second regions to be isolated from each other; and
forming a second resist pattern by second developing the third regions to form second opening holes.

2. The method of claim 1, wherein the CAR layer includes a polymer material and a photo acid generator (PAG), and the polymer material has protection groups.

3. The method of claim 2, wherein the PAG is induced to generate the acids and the acids deprotect the protecting groups in the first regions to make the first region soluble in an alkaline developer, in the exposing of the first regions of the CAR layer.

4. The method of claim 2, wherein each of the protecting groups includes an acid labile group that is removed by the acids.

5. The method of claim 2, wherein the acids are induced to remove the protecting groups in a post exposure bake (PEB) process following the exposing of the first regions of the CAR layer.

6. The method of claim 3, wherein the exposed first regions are first developed using the alkaline developer to be removed, in the forming of the first resist pattern.

7. The method of claim 6 wherein the alkaline developer includes a tetramethyl ammonium hydride (TMAH) solution having a concentration of approximately 2.38 wt %.

8. The method of claim 5, wherein the diffusing of the acids remaining in the sidewall portions of the first resist pattern includes:
annealing the first resist pattern at a diffusion temperature which is higher than a baking temperature of the PEB process.

9. The method of claim 8, wherein the diffusion temperature is set higher than the baking temperature by 20 degrees Celsius to 30 degrees Celsius.

10. The method of claim 9, wherein the diffusion temperature is set to be within the range of about 120 degrees Celsius to about 140 degrees Celsius.

11. The method of claim 8, wherein the acids remaining in the sidewall portions are diffused into the second region of the first resist pattern, and the acids diffused into the second region deprotects the protecting groups in the second region to make the polymer material in the second region insoluble in an organic solvent, in the annealing of the first resist pattern.

12. The method of claim 11, wherein the third regions are second developed using the organic solvent as a developer to be removed, in the forming of the second resist pattern.

13. The method of claim 12, wherein the organic solvent includes acetate, alcohol, ether, ester or ketone.

14. The method of claim 8, wherein the diffusing of the acids remaining in the sidewall portions of the first resist pattern further includes:
forming a diffusion promotion layer on the first resist pattern to accelerate diffusion of the acids, before the annealing of the first pattern.

15. The method of claim 14, wherein the diffusion promotion layer includes an acid polymer material.

16. The method of claim 8, herein the annealing of the resist pattern includes:
supplying an acid ambient gas onto the first resist pattern.

17. The method of claim 16, wherein the acid ambient gas includes a hydrochloric acid (HCl) gas.

18. The method of claim 1, wherein each of the second opening holes is formed at a central portion of a region surrounded by three or more adjacent of the first opening holes that are adjacent.

19. A method of forming fine patterns, the method comprising:
performing an exposure process to generate acids in first regions of a chemically amplified resist (CAR) layer;
removing the exposed first regions using a first development process to form a first resist pattern;
diffusing acids in sidewall portions of the first resist pattern into a bulk region of the first resist pattern to form second regions in which the acids are diffused and to form a plurality of third regions between the second regions; and
removing the third regions using a second development process to form second resist patterns.

20. A method of forming fine patterns, the method comprising:
performing an exposure process to generate acids in first regions of a chemically amplified resist (CAR) layer;
removing the exposed first regions using a first development process to form a first resist pattern providing first opening trenches;
diffusing acids in sidewall portions of the first resist pattern into a bulk region of the first resist pattern to form second regions in which the acids are diffused and to form a plurality of third regions in lines between the second regions; and
removing the third regions using a second development process to form second resist patterns providing second opening trenches between the first opening trenches.
